(19) United States
(12) Patent Application Publication
(10) Pub. No.: US 2007/0290321 A1
(43) Pub. Date: Dec. 20, 2007

(54) DIE STACK CAPACITORS, ASSEMBLIES AND METHODS

(75) Inventor: Lance L. Sundstrom, Pinellas Park, FL (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International Inc., Morristown, NJ (US)

(21) Appl. No.: 11/424,019

(22) Filed: Jun. 14, 2006

(51) Int. Cl. H01L 23/48

(52) U.S. Cl. 257/690

(57) ABSTRACT

Chip and wire and flip chip compatible die stack capacitors (“stack caps”), die stack assemblies and die stack assembly methods are disclosed. Each stack cap includes a plurality of multilayer sections. Each multilayer section is fabricated separately, and the sections are then bonded or integrated together. As illustrative examples, stack cap formats with peripheral ring wire bond terminals or interfacial attach pad terminals along with their associated die stack assemblies and assembly methods are disclosed. Each stack cap is attached directly to the IC die that it bypasses. The respective peripheral power, ground and signal bond pads of each bonded stack cap and die pair and the host substrate are connected with bond wires.

### FIELD OF THE INVENTION

The present invention relates to the field of integrated circuits (ICs), and more particularly, but not exclusively, to improved bypassing of IC die with special die stack capacitors.

### BACKGROUND OF THE INVENTION

Increases in IC die circuit and power densities, input/output (I/O) counts, output edge rates, and drive strengths along with decreases in output skew have resulted in increased die power and ground rail current magnitudes and rates of change (di/dt). The increased die rail currents cause such problems as die rail bounce and rail span collapse relative to the connected rails of the host printed wiring board (PWB). Essentially, die rail bounce is a fluctuation in the voltage of the die rail relative to the connected rail of the host PWB, which is caused by the magnitude and rate of change of current flow through the resistive and inductive components of the connection paths. This can occur when multiple outputs switch simultaneously in the same direction. Die rail span collapse is the difference between the differential voltages across the die and PWB rails, which is caused by the magnitude and rate of current flow through the resistive and inductive components of the connected power and ground paths. This can occur with dynamic increases in die power dissipation (steps and spikes) and radiation dose rate induced photocurrents in military and space environments. To make matters worse, the use of lower die operating voltages has resulted in a lower tolerance to the effects of rail bounce and rail span collapse. The voltage range over which IC operation is guaranteed is typically a small percentage change about its nominal supply voltage (e.g., ±5% or ±10%). The guaranteed operating voltage range decreases with supply voltage.

Additionally, IC packages continue to shrink in size. Consequently, the conventional approach is to move chip bypass capacitors out and/or off of the IC package and onto the host PWB. The resulting longer path lengths between the die and its bypass capacitance has increased the effective equivalent series inductance (ESL) and equivalent series resistance (ESR) of its bypass capacitance, and lowered its effectiveness. One compensation technique to increase effectiveness is to increase the number of PWB-mounted bypass capacitors used. However, the space saved on the PWB by smaller IC packaging is offset by the space taken up by the additional PWB mounted chip capacitors needed for effective bypassing.

Thus, more effective die bypass capacitance is needed to ensure that the problems of die rail bounce and die rail span collapse do not occur due to the higher rail currents and lower guaranteed operating rail voltage ranges being used over the operating frequency range of the IC involved. Also, effective die bypassing requires the use of a technique that minimizes the ESL and ESR between the die and its bypass capacitance, and ensures that the bypass capacitance network has no impedance poles within or near the operating frequency range of the die (e.g., between the minimum clock frequency and the maximum effective edge rate frequency). This ensures that the effective die power rail impedances remain low over this entire frequency range.

FIGS. 1-3 depict, respectively, a side/elevation, top/plan view and detailed side/elevation views of a dual die stack arrangement including a plurality of stacked capacitors (“stack caps”), which are disclosed in commonly-assigned U.S. Pat. No. 5,864,177 entitled “BYPASS CAPACITORS FOR CHIP AND WIRE CIRCUIT ASSEMBLY” issued Jan. 26, 1999 (hereinafter, the “'177 patent”). The '177 patent is incorporated herein in its entirety. The stack caps disclosed in the '177 patent are monolithic planar capacitors with continuous peripheral tiered wire bond contacts that provide multiple advantages such as die bypass capacitance, backside termination for the upper die, and spacing between die. Specifically, each stack cap in the '177 patent is a monolithic planar capacitor, which is intended for direct interfacial conductive and/or nonconductive attachment and/or wire bonding to each die of a die stacked assembly disposed on a host substrate (e.g., IC package or PWB). Although primarily providing a stack cap format for wire bond assembly, the die stack assemblies provided by the '177 Patent includes single wire bond dies or flip chip dies, special stack cap compatible dies, or multiple combinations of stack caps and/or stacked dies.

In the '177 patent, each die and its bypass capacitance are co-located and interconnected with multiple (short) interfacial conductive bonds and/or bond wires, which provides an exceptionally low ESR and ESL between each die and its bypass capacitances. (The only interfacial bonds included a single non-conductive bond to the lower die and a single conductive bond to the upper die.) The stack cap provides space between the stacked dies (e.g., for bond wires) and an optional termination for the upper die. The power and ground plates of each stack cap are connected in parallel with the power and ground rails of the respective die, which reduces the effective die rail impedance. Also, the power and ground plates of the stack caps function as shields over the respective die, which improves the electromagnetic interference (EMI) and radiation immunity of each die. Notwithstanding the numerous advantages of the stacked die arrangements disclosed in the '177 Patent, a problem that exists with this chip and wire die stacked assembly is that because of the tiered peripheral wire bond contact arrangements used, fabricating a monolithic version of this stack cap is an exceptionally complicated and difficult process with just a conventional multilayer green tape punch, print, dry, stack and cofire process used in the fabrication of multilayer ceramic substrates and IC packages. This process relies on buried and blind vias to make connections between layers. As such, there is a trade-off between multiple parallel via connections for low plane-plane impedance and the loss of capacitance due to via clearance holes in the capacitance plates. Therefore, a pressing need exists for chip and wire compatible stack caps in which multilayer sections can be fabricated separately and then bonded or integrated together, which reduces the difficulty of the fabrication process, improves the volumetric efficiency (capacitance to volume ratio) and reduces its ESL and ESR. As described in detail below, the present invention provides such assembled and integrated stack cap formats which resolve the above-described fabrication problems, bypass capacitance effectiveness problems, and other related problems. The assembled versions of the present invention are more easily tailored to a particular application, wherein adapter substrates can be sized for standard die sizes, and a standard value low ESL and ESR planar chip capacitor (e.g., as described in U.S. Pat. No. 7,016,176) can be selected for the particular die function and application.

### SUMMARY OF THE INVENTION

Chip and wire compatible stack caps, die stack assemblies and assembly methods are provided. Each stack cap includes a plurality of multilayer sections. Each multilayer section is fabricated separately, and the sections are then bonded or laminated together. As one example embodiment, a stack cap assembly with peripheral ring wire bond terminals is provided, which includes a planar low ESL and ESR capacitor and top and bottom adapter substrates. The bottom attach pads of the planar low ESL and ESR capacitor are conductively bonded to the mating top attach pads of a bottom adapter substrate with peripheral ring wire bond terminals. The bottom mating attach pads of a top adapter substrate are conductively bonded to the top attach pads of the planar low ESL and ESR capacitor. The assembled and tested stack cap can then be bonded to the top surface of a chip and wire die or the backside of a flip chip die. The respective peripheral power, ground and signal wire bond terminals of the stack cap, die and host substrate are connected with wire bonds. An example application for the present invention is an assembly that includes a flip chip field-programmable gate array (FPGA) die and its configuration programmable read-only memory (PROM) die (a fully self-contained solution).

### BRIEF DESCRIPTION OF THE DRAWINGS

The novel features believed characteristic of the invention are set forth in the appended claims. The invention itself, however, as well as a preferred mode of use, further objectives and advantages thereof, will best be understood by reference to the following detailed description of an illustrative embodiment when read in conjunction with the accompanying drawings, wherein:

FIG. 1 depicts a side/elevation cross-section view of an existing dual die stack arrangement including a plurality of stacked capacitors;

FIG. 2 depicts a top/plan view of the existing dual die stack arrangement shown in FIG. 1;

FIG. 3 depicts a detailed side/elevation cross-section view of the existing dual die stack arrangement shown in FIGS. 1 and 2;

FIG. 4 depicts a top/plan view and side/elevation cross-section view (minus bond wires) of an example chip and wire die stack assembly, which can be used to implement a first example embodiment of the present invention;

FIG. 5 depicts a side/elevation cross-section view of a chip and wire compatible stack cap assembly, which uses a tiered configuration of stacked SLCs to implement an example embodiment of the present invention;

FIG. 6 depicts bottom, side and top views of a low ESL and ESR planar chip capacitor, which can be used to implement a second example embodiment of the present invention;

FIG. 7 depicts top/plan and side/elevation views of a bottom adapter substrate, which can be used to implement an example embodiment of the present invention;

FIG. 8 depicts the bottom, side and top views of a top adapter substrate, which can be used to implement an example embodiment of the present invention;

FIG. 9 depicts top/plan and side/elevation cross-section views of a chip and wire compatible stack cap assembly (minus bond wires), which illustrates how the exemplary planar chip capacitor and top and bottom adapter substrates depicted in FIGS. 6-8 can be conductively attached together, in accordance with a preferred embodiment of the present invention;

FIG. 10 depicts a detailed side/elevation cross-section view of a chip and wire die stack assembly, which can be used to implement wire bonding for the chip and wire compatible stack cap assemblies shown in FIG. 9;

FIG. 11 depicts the bottom, side and top views of an assembled or monolithic stack cap with top and bottom attach pad arrays, which can be used to implement an embodiment of the present invention;

FIG. 12 depicts the top/plan view and side/elevation cross-section view (minus bond wires) of a chip and wire die stack assembly, which includes a plurality of interfacially connected stack caps, such as the planar chip capacitor shown in FIG. 11;

FIG. 13 is a flowchart depicting a method for assembling a die stack assembly, in accordance the example embodiments of the present invention.

### DETAILED DESCRIPTION OF PREFERRED EMBODIMENT

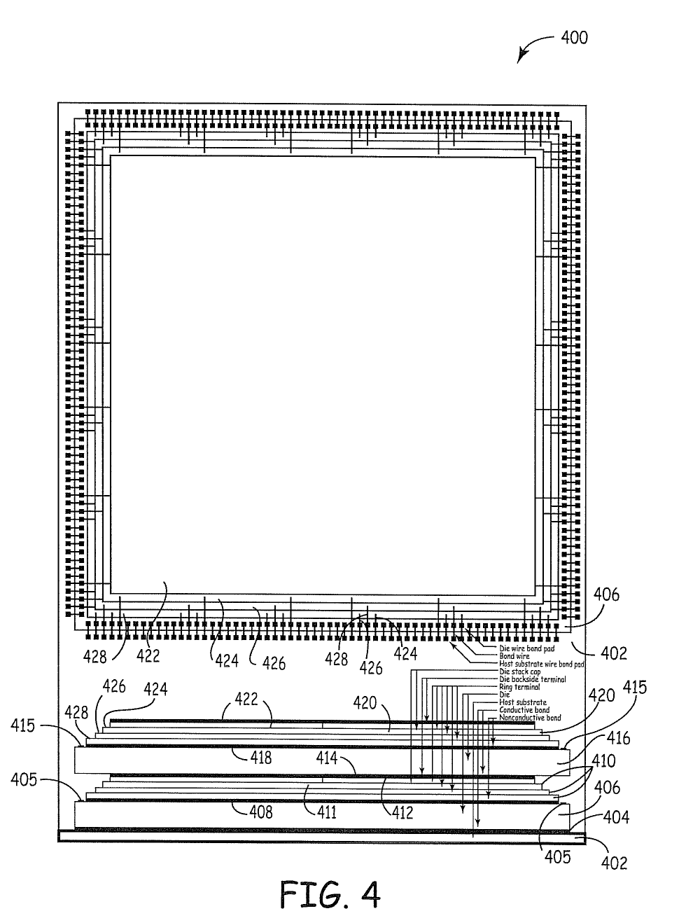

With reference flow to the figures, FIG. 4 depicts top/plan and side/elevation cross-section views of an example chip and wire die stack assembly 400, which can be used to implement an exemplary embodiment of the present invention. Bond wires are deleted from the side/elevation cross-section view for clarity. For this example embodiment, die stack assembly 400 includes a host substrate 402 (e.g., an IC package or PWB), a first bond material 404 (conductive or nonconductive as required) disposed on the top surface of host substrate 402 within its peripheral wire bond terminals 401. A first die 406 is disposed on the top surface of first bond material 404 such that the bottom surface of first die 406 is bonded to the top surface of host substrate 402 within its peripheral wire bond terminals 401. A second bond material 408 (conductive or nonconductive as required) is disposed on the top surface of first die 406 within its peripheral wire bond terminals 405. A first stack cap 411 is disposed on the top surface of second bond material 408 such that the bottom surface of first stack cap 411 is bonded to the top surface of first die 406 within its peripheral wire bond terminals 405. Corresponding first die 406 and host substrate 402, signal wire bond terminals 405 and 401 are connected with bond wires as shown. Corresponding first stack cap 411, first die 406 and host substrate 402, power and ground terminals 410, 405 and 401 are connected with stitch bond wires as shown.

A third bond material 414 (conductive or nonconductive as required) is disposed on the top surface of first stack cap 411. A second die 416 is disposed on the top surface of third bond material 414 such that the bottom surface of second die 416 is bonded to the top surface of first stack cap 411. A fourth bond material 418 (conductive or nonconductive as required) is disposed on the top surface of second die 416 within its peripheral wire bond terminals 415. A second stack cap 420 is disposed on the top surface of fourth bond material 418 such that the bottom surface of second stack cap 420 is bonded to the top surface of second die 416 within its peripheral wire bond terminals 415. Respective die 416 and host substrate 402, signal wire bond terminals 415 and 401 are connected with bond wires as shown. Respective second stack cap 420, second die 416 and host substrate 402, power and ground bond terminals 420, 415 and 401 are connected with stitch bond wires as shown. Thus, assembly 400 provides a stacked arrangement of IC die and stack caps, wherein each die and its stack cap is collocated and connected with multiple short stitch bond wires regardless of die stack position.

Essentially, the chip and wire stack cap arrangement shown in FIG. 4 advantageously minimizes the ESR and ESL of each die's bypass capacitance. This arrangement also provides noise isolation between the power and ground rails of the die and substrate. This allows combinations of analog, digital and radio frequency (RF) die within the same die stack assembly. The vertical separation of its peripheral tiered contacts prevents wire bond shorts across terminals, but it also makes monolithic fabrication difficult and expensive. However, in accordance with teachings of the present invention, each multilayer section of each stack cap in assembly 400 can be fabricated separately and then conductively bonded or integrated together, which minimizes the difficulty of the fabrication process and also the number of multilayer sections needed (depending on the particular application desired).

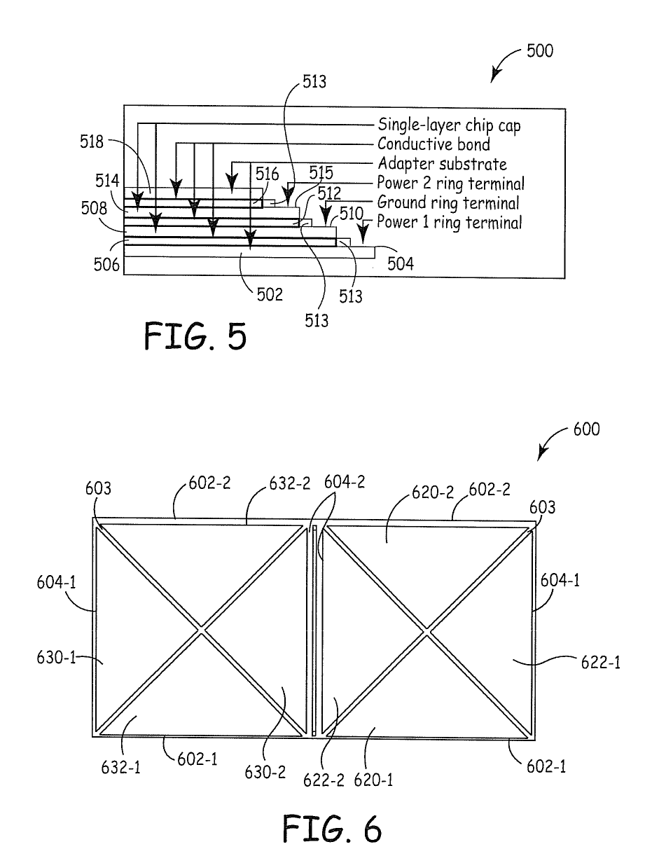

For example, if less capacitance than that provided by the capacitors in assembly 400 is desired, a chip and wire compatible, tiered stack cap configuration that can be used is disclosed in FIG. 5. As such, FIG. 5 depicts a chip and wire compatible stack cap assembly 500, which uses a tiered configuration of stacked SLCs to implement an example embodiment of the present invention. For this example embodiment, stack cap assembly 500 includes a first adapter substrate 502 with a metalized top surface. The metalized bottom surface of a first SLC 508 is bonded to the metalized top surface of first adapter substrate 502 with a suitable conductive bond material 506. As shown, the area (e.g., footprint size) of first SLC 508 is less than the area of first adapter substrate 502, and first SLC 508 is disposed within the periphery of first adapter substrate 502. The exposed metalized top surface at the periphery of first adapter substrate 502 serves as a first ring terminal 504. The metalized bottom surface of a second SLC 514 is bonded to the metalized top surface of first SLC 508 with a suitable conductive bond material 512. The area of second SLC 514 is less than the area of first SLC 508, and second SLC 514 is disposed within the periphery of first SLC 508. The exposed metalized top surface at the periphery of first SLC 508 serves as a second ring terminal 510. The metalized bottom surface of a second adapter substrate 518 is bonded to the metalized top surface of second SLC 514 with a suitable conductive bond material 516. The area of second adapter substrate 518 is less than the area of second SLC 514, and second adapter substrate 518 is disposed within the periphery of second SLC 514. The exposed metalized top surface at the periphery of second SLC 514 serves as a third ring terminal 515. The first, second and third ring terminals 504, 510 and 515 would typically be assigned as first power, common ground and second power, respectively. Notably, the conductive bond material(s) used in stack cap assembly 500 may be any conductive bond material that is suitable for ICs. However, if solder or a similar material is used for the conductive bond material, then solder dams 513 may be used in assembly 500 to keep the peripheral wire bond tiers free of excess solder material. Ultimately, for this example embodiment, stack cap assembly 500 is pre-tested and bonded with a suitable non-conductive bond material to the top surface of a chip and wire die assembly (not shown). The first power ring terminal 504, the common ground ring terminal 510, and the second power ring terminal 515 of die stack assembly 500 are then stitch wire bonded to the corresponding first power, common ground and second power bond pads of the die and host substrate (not shown), respectively, as with assembly 400 in FIG. 4. This implementation may not be preferred, because the total bypass capacitance value may be too low to be effective over the entire frequency range. However, this implementation may provide enough bypass capacitance to supplement the high frequency performance of conventional chip capacitors mounted inside and/or on the host package and/or PWB.

FIG. 6 depicts a special chip capacitor, which can be used with adapter substrates and conventional chip and wire die, or directly with die with compatible top and bottom attach pads, to implement second and third example embodiments of the present invention. Essentially, FIG. 6 depicts the bottom, side and top views of a special, thin, planar, high volumetric efficiency and low ESL and ESR chip capacitor 600, which includes two wrap around power (top and bottom) terminals and two wrap around ground (left and right) terminals. Notably, the planar chip capacitor 600 of FIG. 6 is disclosed in commonly-assigned U.S. Pat. No. 7,016,176, entitled “LOW ESL AND ESR CHIP CAPACITOR” issued Mar. 21, 2006, which is incorporated herein in its entirety. Specifically, referring to the top view in FIG. 6, chip capacitor 600 includes a first terminal composed of first wrap around terminal sections 602-1 and 602-2, and a second terminal composed of second wrap around terminal sections 604-1 and 604-2. Referring now to the top view in FIG. 6, which illustrates the entire top attaching surface of chip capacitor 600, the first terminal section 602-1 of the first terminal includes the top interfacial attach section 620-1, and the first terminal section 602-2 of the first terminal includes the top interfacial attach section 620-2. The second terminal section 604-1 of the second terminal includes the top interfacial attach section 622-1, and the second terminal section 604-2 of the second terminal includes the top interfacial attach section 622-2. As shown in the top and bottom views of FIG. 6, the first terminal sections 602-1, 602-2 and the second terminal sections 604-1, 604-2 are each split into triangular sections separated by an isolation layer 603 (e.g., composed of air or a material having a relatively high resistance to current flow).

Referring now to the bottom view in FIG. 6, which illustrates the entire bottom attaching surface of chip capacitor 600, the first terminal section 602-1 includes a bottom interfacial attach section 632-1, and the first terminal section 602-2 includes a bottom interfacial attach section 632-2. Also, the second terminal section 604-1 includes a bottom interfacial attach section 630-1, and the second terminal section 604-2 includes a bottom interfacial attach section 630-2. The first and second bottom interfacial attach sections 632-1, 632-2, 630-1 and 630-2 are adapted to be attached to a mating capacitor footprint of a host substrate. As shown, the top first and second interfacial attach sections 622-1, 622-2, 620-1 and 620-2, and the bottom first and second interfacial attach sections 632-1, 632-2, 630-1 and 630-2 are separated by the two parts of x-shaped isolation gaps 603. Thus, substantially the entire potential top and bottom attaching area of chip capacitor 600 is covered by top and bottom first and second interfacial attach sections 622-1, 622-2, 620-1, 620-2, 632-1, 632-2, 630-1 and 630-2, which minimizes or eliminates the conventional need for side fillets.

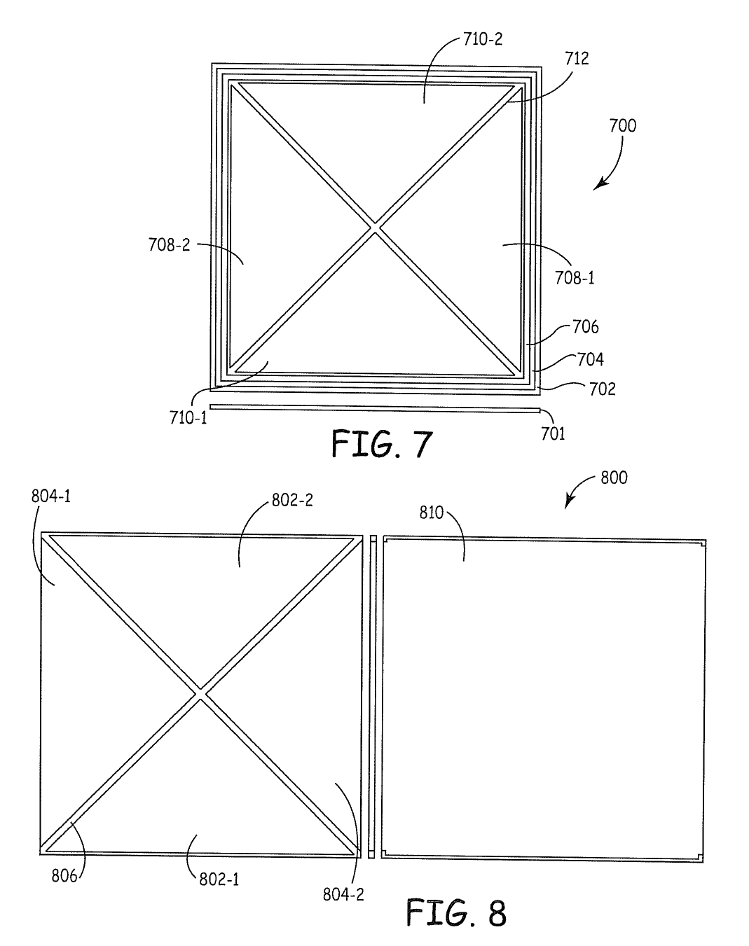

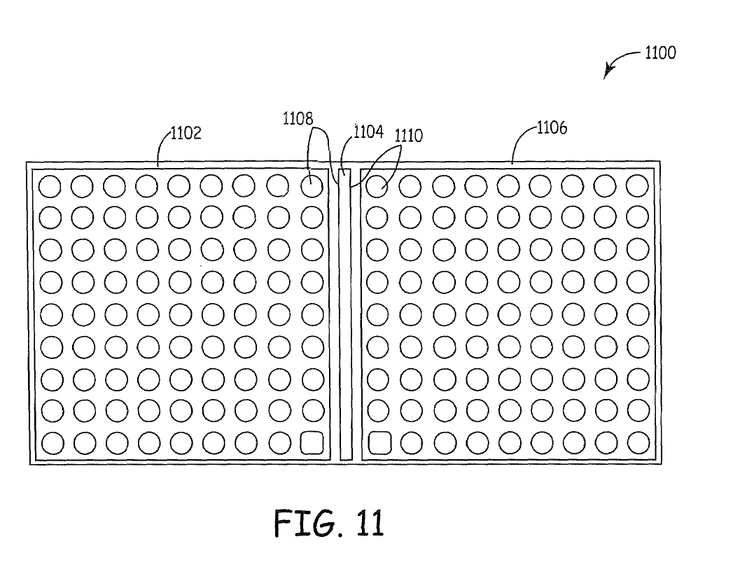

FIG. 7 depicts the top/plan and side/elevation views of a bottom adapter substrate 700 arrangement that can be used to implement an example embodiment of the present invention. For this example embodiment, bottom adapter substrate 700 includes internal power and ground planes that can be used in accordance with the teachings of the present invention to connect the bottom interfacial attach pads of a planar chip capacitor 600 (FIG. 6) to peripheral power and ground wire bond rings. Specifically, referring to FIG. 7, bottom adapter substrate 700 includes two planar capacitor attach terminals composed of two terminal sections each. The two terminal sections of the first terminal include bottom and top attach terminal sections 710-1, 710-2. The two terminal sections of the second terminal include right and left attach terminal sections 708-1 and 708-2. The first and second terminal sections are each split into triangular sections separated by an isolation layer 712. Bottom adapter substrate 700 also includes a first power ring terminal 702, a first ground ring terminal 704, and a second power ring terminal 706. If fabricated with a successive print, dry and fire of thick film conductors and dielectrics on a supporting substrate 701, the peripheral ring terminals could be tiered. If fabricated with a multilayer green tape co-fire process, the peripheral ring terminals would be disposed on the same layer, as shown in FIG. 10.

FIG. 8 depicts the bottom, side and top views of a top adapter substrate 800 arrangement that can be used to implement an example embodiment of the present invention. For this example embodiment, top adapter substrate 800 includes bottom, top and wrap around edge metalizations that can be used to connect the power or ground attach pads of a bottom planar chip capacitor to the top die backside attach pad. Specifically, referring now to the bottom view in FIG. 8, which illustrates the entire mating attaching surface for the chip capacitor involved, a first terminal section of the chip capacitor includes two interfacial attach sections 802-1 and 802-2. Also, a second terminal section includes two interfacial attach sections 804-1 and 804-2. The first and second terminal interfacial attach sections 802-1, 802-2, 804-1 and 804-2 are adapted to be attached to a mating planar chip capacitor 600 (FIG. 6). As shown, the first and second interfacial attach sections 802-1, 802-2, 804-1 and 804-2 are separated by the two parts of x-shaped isolation gap 806. The top die backside attach section of the assembly is identified generally as element 810.

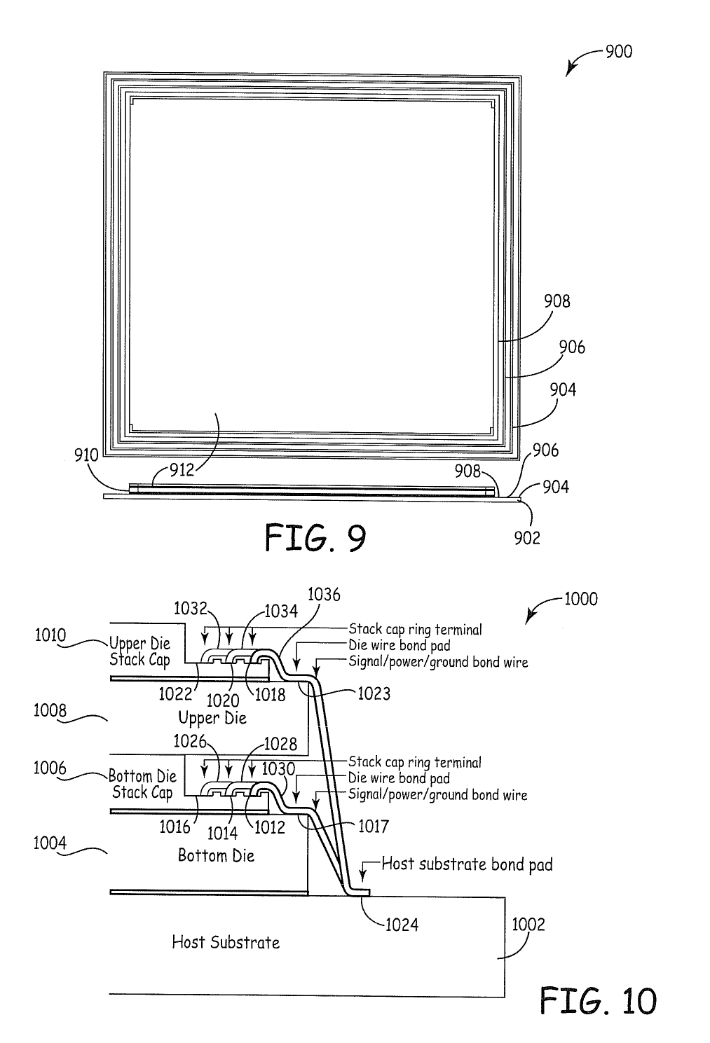

FIG. 9 depicts a chip and wire compatible stack cap assembly 900, which illustrates how the exemplary planar chip capacitor and top and bottom adapter substrates depicted in FIGS. 6-8 can be conductively attached together, in accordance with the teachings of the present invention. This is the preferred embodiment for a chip and wire compatible stack cap assembly for conventional chip and wire die, wherein the die do not have compatible direct interfacial stack cap attach pads. Note that the top adapter substrate could be eliminated if a custom or modified low ESL and ESR planar chip capacitor with just a die backside attach terminal on its top side is used. Notably, the top and bottom adapter substrates depicted in FIGS. 6-9 can accept various sizes and values of planar chip capacitors. Note that square planar chip capacitors of various sizes can be attached to this footprint, and in each case, the capacitor is self-aligned to the center. Consequently, the chip and wire compatible stack cap assemblies provided by the present invention can be readily tailored to fit the particular technical applications involved. Referring now to FIG. 9 for this example embodiment, stack cap assembly 900 includes a bottom adapter substrate 902, with a first power ring terminal 904, ground ring terminal 906, and second power ring terminal 908 disposed on the peripheral top surface of bottom adapter substrate 902. The bottom attach terminals of a planar chip capacitor 910 are conductively bonded to the mating top attach terminals of bottom adapter substrate 902. The mating bottom attach terminals of top adapter substrate 912 are conductively bonded to the top attach terminals of planar chip capacitor 910. The stack cap assembly is pre-tested prior to use in a die stack assembly.

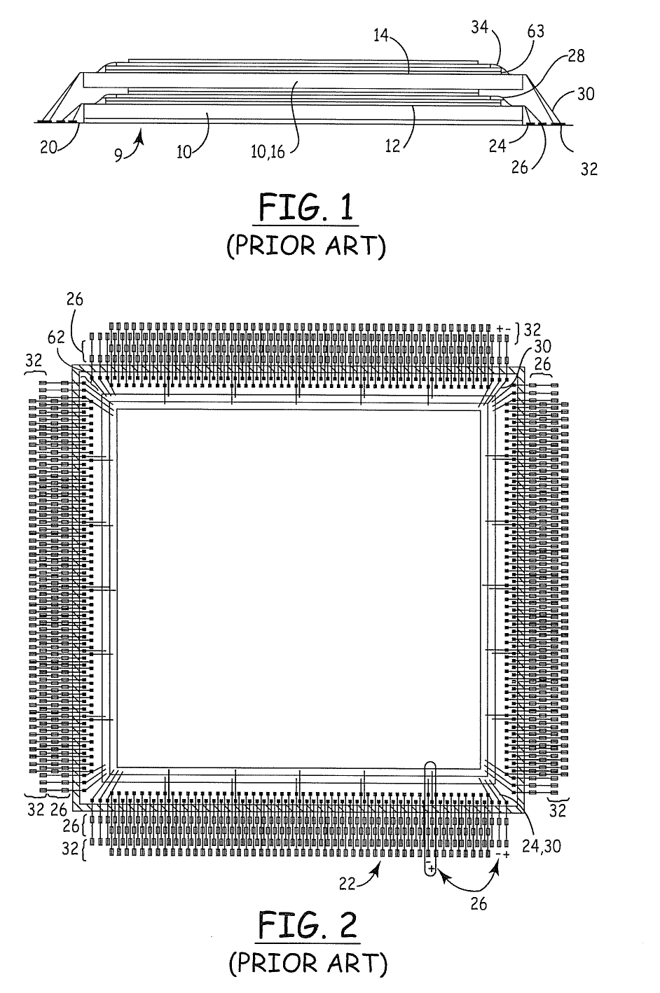

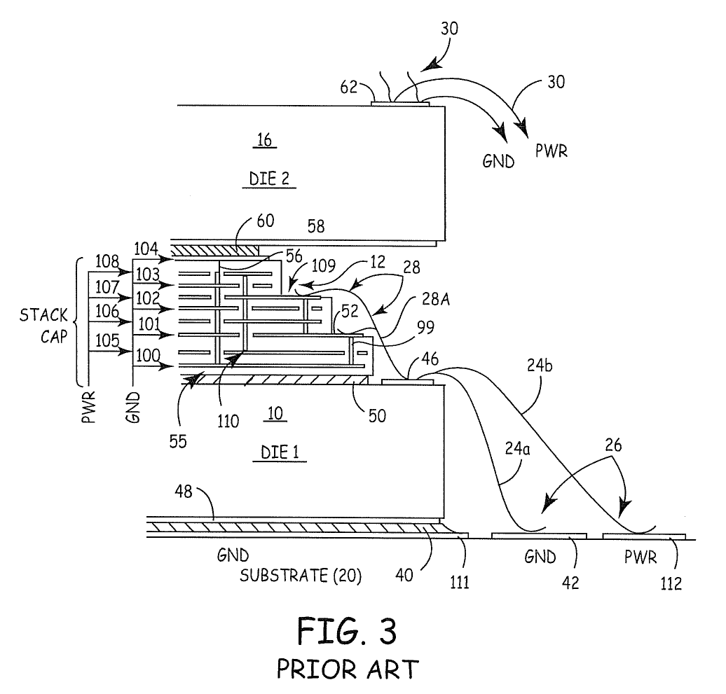

FIG. 10 depicts a tiered, chip and wire die stack assembly 1000, which can be used to implement assembly and wire bonding of die stack assemblies with the chip and wire compatible stack caps shown in FIGS. 1-5 and 9. The wire bond pattern shown implies thermosonic gold ball bonding wherein the first gold ball bond exits normal to its wire bond pad surface, and the second wedge bond exits parallel to its wire bond pad surface. With ultrasonic wire bonding, both the first and second wedge bonds exit parallel to their wire bond pad surfaces. For coplanar peripheral ring terminals, the stitch bond wires must be carefully dressed to avoid wire bond shorts between the ring terminals. The tiered ring terminals shown in FIGS. 1-5 and the thick film bottom adapter substrate shown in FIGS. 7 and 9 provide vertical separation between peripheral ring terminals to help prevent wire bond shorts. For this example embodiment, chip and wire die stack assembly 1000 includes a host substrate 1002 (e.g., a host IC package or PWB). A first die 1004 is conductively bonded to the top surface of host substrate 1002, a first stack cap 1006 is non-conductively bonded to the top surface of first die 1004, a second die 1008 is conductively bonded to the top surface of first stack cap 1006, and a second stack cap 1010 is non-conductively bonded to the top surface of second die 1008. A first plurality of ring terminals (e.g., power1/ground/power2) 1012, 1014 and 1016 are disposed at the periphery of first stack cap 1006, and a second plurality of ring terminals 1018, 1020 and 1022 are disposed at the periphery of second stack cap 1010. A first plurality of power2/ground/power1 bond wires 1026, 1028, 1030 are connected (e.g., stitch wire bonded) to respective ring terminals 1016, 1014, 1012 of first stack cap 1006, respective wire bond pads (e.g., represented by wire bond pad 1017) of first die 1004, and respective wire bond pads (e.g., represented by bond pad 1024) of the host substrate 1002. A first plurality of signal bond wires (not shown) are connected to respective wire bond pads (e.g., represented by wire bond pad 1017) of first die 1004 and respective wire bond pads (e.g., represented by bond pad 1024) of the host substrate 1002. Similarly, a second plurality of power2/ground/power1 bond wires 1032, 1034, 1036 are connected (e.g., wire stitched) to respective ring terminals 1022, 1020, 1018 of second stack cap 1010, respective wire bond pads (e.g., represented by wire bond pad 1023) of second die 1008, and respective wire bond pads (e.g., represented by bond pad 1024) of the host substrate 1002. A second plurality of signal bond wires (not shown) are connected to respective wire bond pads (e.g., represented by wire bond pad 1023) of second die 1008 and respective wire bond pads (e.g., represented by bond pad 1024) of the host substrate 1002.

As one option, the chip and wire die stack assembly 1000 of FIG. 10 can be pre-assembled to form a monolithic device, bonded to the back side of a flip chip die, and wire bonded to a host substrate (e.g., IC package or PWB). Also, for enhanced performance, the peripheral bond wire interface between each die 1004, 1008 and its respective stack cap 1006, 1010 can be replaced with direct interfacial conductive bonds. In this case, the top and bottom surface of each die can be metalized with mating planar chip capacitor attach pads, which can be specially plated as needed for direct solder or conductive polymer attach. For direct conductive polymer attach, a suitable polymer mask that promotes selective polymer whetting can be used. A thin planar chip capacitor can then be used directly as a stack cap to provide bypass capacitance for the bottom die, terminate the backside of the top die, and provide a suitable space between the two die to allow for placement of the peripheral bond wires. Advantageously, the selective whetting of solder or conductive polymer (e.g., with a polymer mask) to mating interfacial attach pads enhances self alignment of the arrangement during the assembly process. Note that a die stack assembly could be composed of a bottom microprocessor flip chip die with its stack cap bonded to its top side plus one or more cache memory die and stack cap pairs bonded on top of that. This tightly integrated processor and memory combination would significantly increase performance while reducing package size and weight.

As another option, if additional power and ground distribution is required across the surface of a die, the triangular interfacial attach pads of the die and planar chip capacitor can be replaced with a suitable attach pad array. Such an attach pad array arrangement can be integrated into the planar chip capacitor or provided by adapter substrates. As an illustrative example, FIG. 11 depicts the bottom, side and top views of a thin planar chip capacitor 1100 with top and bottom attach pad arrays. Note that this stack cap could be fabricated as an assembly of the low ESL and ESR chip capacitor shown in FIG. 6 and top and bottom adapter substrates. Also, this stack cap could be fabricated as a monolithic block similar to the low ESL and ESR chip capacitor shown in FIG. 6 with edge metallization plane-to-plane connections plus blind via plane to attach pad array connections. The bottom attach pad array composes the power and ground terminals. The top attach pads are all connected to power and ground as needed to terminate the back side of the upper die. For this example embodiment, planar chip capacitor 1100 includes an M by N array of attach pads (e.g., exemplified by the individual bottom and top attach pads 1108, 1110), where M and N in this example are each equal to nine.

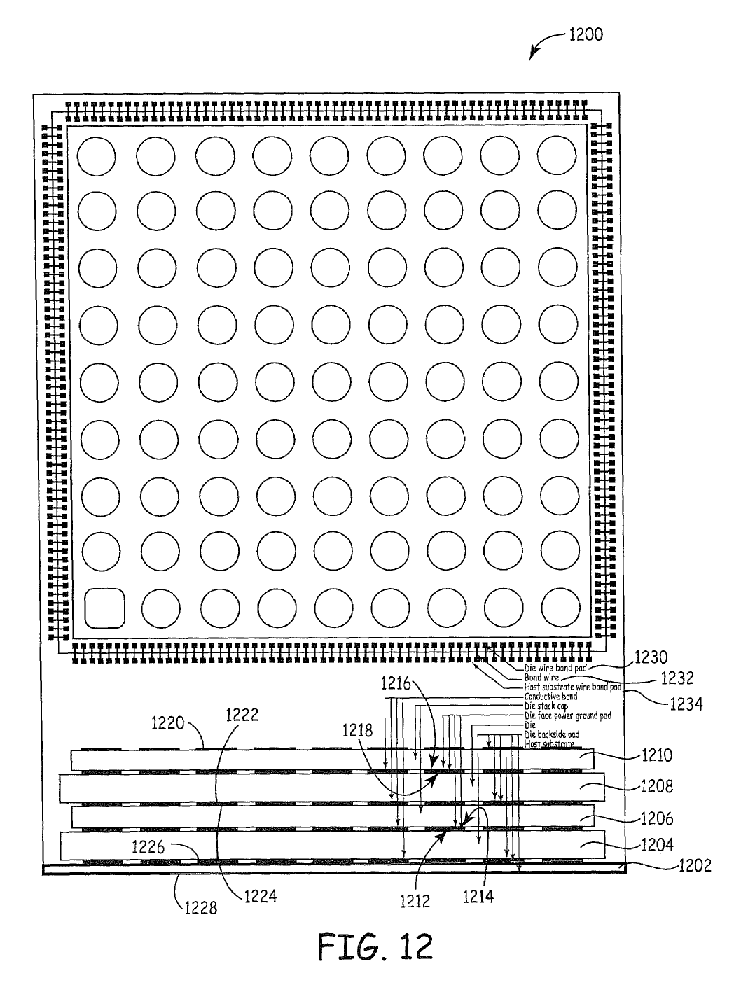

FIG. 12 depicts the top/plan view and side/elevation cross-section view (minus bond wires) of a chip and wire die stack assembly 1200, which includes a plurality of interfacially connected stack caps, such as the planar chip capacitor 1100 of FIG. 11 as shown, or the planar chip capacitor 600 of FIG. 6 (not shown here). This assembly is preferred for die with compatible top and bottom attach pads, because it eliminates the need for peripheral stitch wire bonds connections, provides distributed filtered power across the entire die, and lowers the effective impedance of the die power and ground rails. Note again that selective whetting of solder bonds or conductive polymer bonds (e.g., using a polymer mask) promotes self alignment during the assembly process. The direct interfacial conductive bonds provide lower ESL and ESR than peripheral stitch bond wires. Referring to FIG. 12, assembly 1200 includes a host substrate 1202, a first (bottom) die 1204 conductively bonded to the top surface of host substrate 1202, a first stack cap 1206 conductively bonded to the top surface of first die 1204, a second (top) die 1208 conductively bonded to the top surface of first stack cap 1206, and a second stack cap 1210 conductively bonded to the top surface of second die 1208. Assembly 1200 also includes a plurality (e.g., an array) of die face interfacial power and ground bonds (exemplified by first die 1204 and first stack cap 1206 mating power/ground attach pads 1212, 1214, and second stack cap 1210 and second die 1208 mating power/ground attach pads 1216, 1218), and a plurality (e.g., array) of die backside attach pads (exemplified by second die 1208 and first stack cap 1206 backside mating attach pads 1222 and 1224, and first die 1204 and host substrate 1202 backside mating attach pads 1226 and 1228). Also, assembly 1200 includes a plurality of die wire bond pads, bond wires, and host substrate wire bond pads arranged around the periphery of assembly 1200 (exemplified by die wire bond pad 1230, bond wire 1232, and host substrate wire bond pad 1234). As shown, for this example, assembly 1200 is arranged with a plurality of 9 by 9 arrays of top and bottom interfacial attach pads.

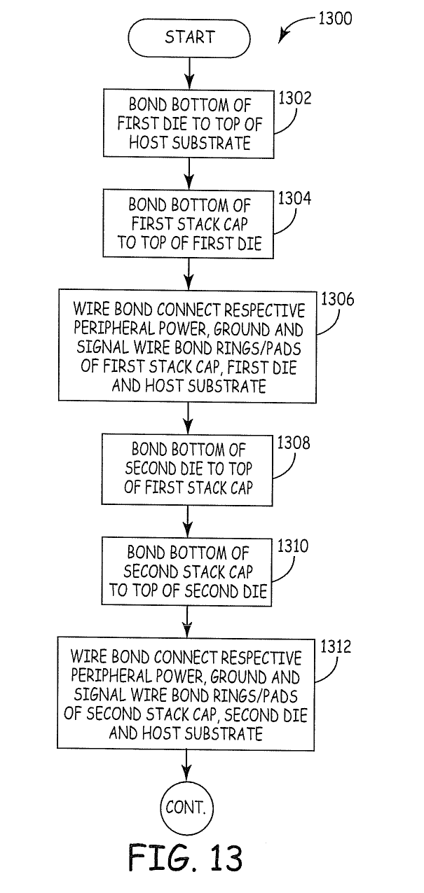

The sequence for assembling a die stack assembly is essentially the same, regardless of die type (chip and wire or flip chip) or whether or not the substrate, die or stack cap have mating interfacial attach pads. FIG. 13 is a flowchart depicting method 1300 for assembling a die stack assembly. Referring to FIG. 13, method 1300 describes a sequence of steps for assembling a die stack assembly. For the example embodiments of the present invention, referring to FIG. 10 or 12 and 13, the chip and wire die stack assembly method bonds the bottom surface of first die 1004 or 1204 to the top surface of host substrate 1002 or 1202 (step 1302). Next, the bottom surface of first stack cap 1006 or 1206 is bonded to the top surface of first die 1004 or 1204 (step 1304). The respective peripheral power, ground and signal wire bond terminals of first stack cap 1006 or 1206, first die 1004 or 1204 and host substrate 1002 or 1202 are then wire bonded together (step 1306). Next, the bottom surface of second die 1008 or 1208 is bonded to the top surface of first stack cap 1006 or 1206 (step 1308). Next, the bottom surface of second stack cap 1010 or 1210 is bonded to the top surface of second die 1008 or 1208 (step 1310). The respective peripheral power, ground and signal wire bond terminals of second stack cap 1010 or 1210, second die 1008 or 1208 and host substrate 1002 or 1202 are wire bonded together (step 1312). The assembly process may continue with additional die and stack caps in a similar fashion. Depending on the application and particular bond interface, interfacial bonding may be performed with a suitable conductive bond material between each of one or more mating interfacial attach pads or with a non-conductive bond material where mating interfacial attach pads are not present. In the case of a stack cap with peripheral power and ground ring terminals bonded to a conventional chip and wire die, the respective peripheral power and ground terminals of the stack cap, die and host substrate are connected with 3-point stitch bond wires, and the respective peripheral signal wire bond terminals of the die and host substrate are connected with conventional 2-point bond wires. In the case of a stack cap with peripheral power and ground ring wire bond terminals bonded to the backside of a conventional flip chip die, the respective peripheral power and ground wire bond terminals of the stack cap and the host substrate are connected with conventional 2-point bond wires. In the case of a stack cap with interfacial power and ground attach pad terminals bonded to the mating attach pad terminals of a die, the respective peripheral power, ground and signal wire bond terminals of the stack cap, die and host substrate are connected with conventional 2-point bond wires.

The description of the present invention has been presented for purposes of illustration and description, and is not intended to be exhaustive or limited to the invention in the form disclosed. Many modifications and variations will be apparent to those of ordinary skill in the art. These embodiments were chosen and described in order to best explain the principles of the invention, the practical application, and to enable others of ordinary skill in the art to understand the invention for various embodiments with various modifications as are suited to the particular use contemplated. For example, a stack cap added to wire bond or flip chip die on a PWB or inside IC packages could eliminate the need for any local bypass capacitors on the host package or PWB.

What is claimed is:

1. A stack cap, comprising:
a first capacitor including at least two terminals;
a first adapter substrate bonded or laminated to the bottom of the first capacitor and connected to at least one of the at least one of its terminals; and
a second adapter substrate bonded or laminated to the top of the first capacitor and connected to at least a second of the at least one of its terminals.

2. The stack cap of claim 1, wherein the capacitor comprises at least one single layer chip capacitor.

3. The stack cap of claim 1, wherein the capacitor comprises a planar multilayer chip capacitor.

4. The stack cap of claim 1, wherein the first adapter substrate includes at least one top peripheral ring wire bond terminal.

5. The stack cap of claim 1, wherein the first adapter substrate includes at least one bottom attach pad terminal.

6. The stack cap of claim 1, wherein the second adapter substrate includes at least one top attach pad terminal.

7. A die stack assembly, comprising:
a first die; and
a first stack cap, wherein the bottom of the first stack cap is bonded to the top of the first die.

8. The die stack assembly of claim 7, further comprising:
a host substrate, wherein a bottom of the first die is bonded to the top of the host substrate.

9. The die stack assembly of claim 7, further comprising:
a host substrate, wherein the bottom of the first die is bonded to the top of the host substrate; and
a first plurality of bond wires that connect respective peripheral power, ground and signal terminals of the first stack cap, the first die and the host substrate.

10. The die stack assembly of claim 7, further comprising:
a host substrate, wherein the bottom of the first die is bonded to the top of the host substrate;
a first plurality of bond wires that connect respective power, ground and signal terminals of the first stack cap, the first die and the host substrate;
a second die, wherein the bottom of the second die is bonded to the top of the first stack cap;
a second stack cap, wherein the bottom of the second stack cap is bonded to the top of the second die; and
a second plurality of bond wires that connect respective power, ground and signal terminals of the second stack cap, the second die and the host substrate.

11. A method for assembling a circuit, comprising the steps of:
bonding a first die to a substrate;
bonding a first capacitor to the top of the first die;
attaching a first plurality of conductors between a plurality of respective power, ground and signal terminals of the first capacitor, the first die and the substrate;
bonding a second die to the top of the first capacitor;
bonding a second capacitor to the top of the second die; and
attaching a second plurality of conductors between a plurality of respective power, ground and signal terminals of the second capacitor, the second die and the substrate.

12. The method of claim 11, wherein the substrate comprises a host substrate.

13. The method of claim 11, wherein the steps of attaching a first and second plurality of conductors comprise:
wire bonding the plurality of respective power, ground and signal terminals of the first capacitor, the first die and the substrate; and
wire bonding the plurality of respective power, ground and signal terminals of the second capacitor, the second die and the substrate.

14. The method of claim 11, wherein at least one of the first capacitor and second capacitor comprises a thin planar chip capacitor.

15. The method of claim 11, wherein at least one of the first capacitor and second capacitor comprises a stack cap.

16. The method of claim 11, wherein the assembly is adapted to minimize die bypass capacitance ESL and ESR and their effects in the circuit.

17. The method of claim 11, wherein the plurality of power and ground terminals include a plurality of peripheral wire bond terminals.

18. The method of claim 11, wherein the power and ground terminals include a plurality of stack cap attach pads.

19. The method of claim 11, wherein the power and ground attach pad terminals are arranged in an array pattern.
